(19) United States
(12) Patent Application Publication
(10) Pub. No.: US 2025/0311254 A1
(43) Pub. Date: Oct. 2, 2025

(54) SEMICONDUCTOR DEVICE STRUCTURE AND METHOD OF MANUFACTURING THE SAME

(71) Applicant: TAIWAN SEMICONDUCTOR MANUFACTURING COMPANY, LTD., Hsinchu (TW)

(72) Inventors: Guanyu LUO, Chiayi County (TW); Chung-Liang CHENG, Changhua County (TW); Sheng-Chau CHEN, Tainan City (TW); Chung-Yi YU, Hsin-Chu (TW)

(21) Appl. No.: 18/616,386

(22) Filed: Mar. 26, 2024

(51) Int. Cl. H10D 1/68; H10D 1/00

(52) U.S. Cl. CPC H10D 1/696; H10D 1/042; H10D 1/716

(57) ABSTRACT

Embodiments of the present disclosure provide a method for forming a semiconductor device structure. The method includes forming an opening extending through one or more first dielectric layers to expose a conductive feature thereunder and forming a barrier structure on the conductive feature. The forming the barrier structure includes selectively forming a metal layer on the conductive feature and performing a plasma treatment on the metal layer to convert at least a portion of the metal layer into a barrier structure. The method further includes depositing a first conductive layer on the barrier structure in the opening, depositing a second dielectric layer on the first conductive layer, and depositing a second conducive layer on the dielectric layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate. The various material layers can also be patterned using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 8 show manufacturing processes for forming a semiconductor device structure with a metal-insulator-metal structure according to one embodiment;

FIGS. 9 to 12 show processes for forming a semiconductor device structure with a metal-insulator-metal structure according to an alternative embodiment;

FIGS. 13 to 18 show processes for forming a semiconductor device structure with a metal-insulator-metal structure according to an alternative embodiment;

FIG. 19 is a process flow showing a method of forming a 3D MIM structure in a semiconductor device structure according to some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Metal-insulator-metal (MIM) capacitors have been commonly used in functional circuits such as mixed signal circuits, analog circuits, radio frequency (RF) circuits, dynamic random access memory (DRAM), embedded DRAM, and logic operation circuits. Different capacitors for different functional circuits may be integrated on the same chip to serve various applications in system-on-chip (SOC) application. An MIM structure includes a thin layer or film of dielectric layer sandwiched between two layers of conductive materials such as two metal layers. The metal layers may be considered as the top electrode and the bottom electrode of the capacitor, respectively. The bottom electrode may be in contact with a conductive feature formed underneath.

At times, the material of the conductive feature that electrically connects one of the electrodes, for example, the bottom electrode, may diffuse through the bottom electrode into the dielectric layer to establish a conductive path between the top and bottom electrodes of the capacitor. The conductive path results in a dielectric failure and short between the top and bottom electrodes to substantially compromise the function of the capacitor. Diffusion of the conductive material into various dielectric materials is a function of electric field and temperature. The thermal or electric stress during the processes for forming the MIM structure, for example, the process for depositing the bottom electrode, may further the diffusion of the conductive material and contaminate the MIM structure. To prevent the conductive material from diffusing into the dielectric material, a barrier layer may be formed between the conductive feature and the bottom electrode. Metal nitride such as tantalum nitride (TaN) effectively blocks the conductive material such as Cu from diffusing into the MIM structures. However, the TaN layer may increase the resistance of the interconnection between the conductive feature and the MIM structure. To reduce the resistance of the MIM structure, a bilayer structure of TaN and Ta may be formed. The TaN/Ta layer may be formed by physical vapor deposition (PVD).

Due to the increasing demand of higher capacitance of the MIM capacitor, the opening in which a 3D MIM capacitor is formed is deeper and deeper. For example, the aspect ratio of the opening is as high as about 13 to form a 3D MIM structure with a capacitance of about 350 fF. The aspect ratio may approach 16 to form a 3D MIM structure with a capacitance of about 1000fF. When the opening is formed with an aspect ratio larger than 13, the thickness of the TaN/Ta layer may result in overhangs that leads to insufficient space for forming the MIM structure within the opening. One way to resolve the overhang and insufficient space issues includes forming a TiN layer formed by atomic layer deposition (ALD) and a PVD Ta layer. However, this approach is very costly and the opening is still marginal.

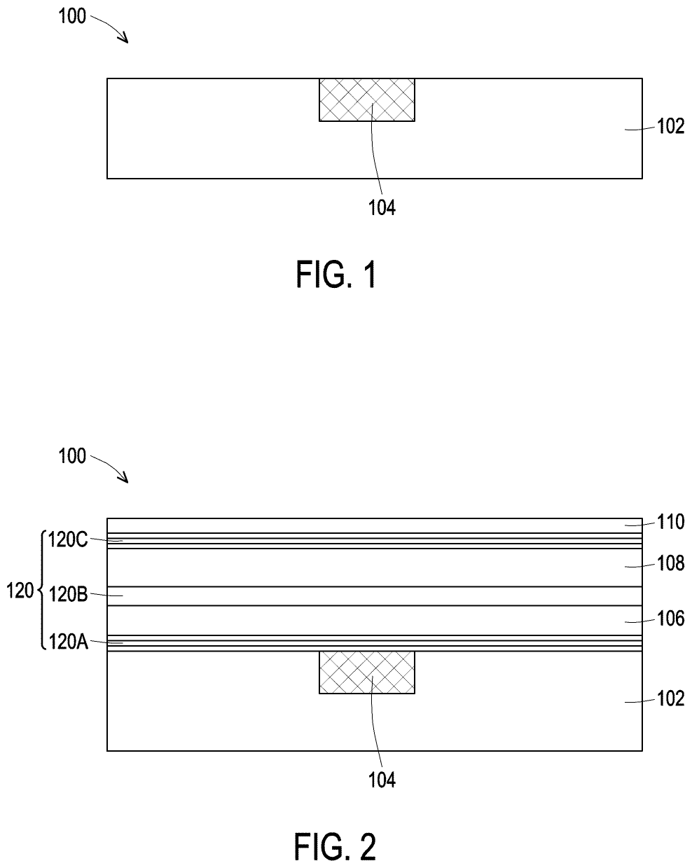

According to some embodiments, FIGS. 1-8 shows various stages of manufacturing a 3D MIM capacitor in a semiconductor device structure. Individual devices may have been formed in a substrate and interconnected with a metallization structure in the respective layers. Such method allows a 3D MIM capacitor to be formed in the metallization structure with sufficient space in a deep opening at a reasonable cost. In the embodiments as shown in FIGS. 1-8, the 3D MIM structure may be formed in the lower metallization levels. For example, the MIM structure may be formed to be in direct contact with the conductive features or electrodes of active or passive devices formed in the substrate. A detailed description with reference to FIGS. 1 to 8 is provided as follows.

FIG. 1 is a cross-sectional view of a semiconductor device structure 100 on which a 3D MIM structure is to be formed. The semiconductor device structure 100 includes a substrate 102 and one or more conductive features 104 formed in the substrate. It will be appreciated that the semiconductor device structure 100 may include any number of conductive features as desired. The substrate 102 may include a silicon (Si) substrate. Alternatively, the substrate 102 may include other elementary semiconductor material such as germanium or compound semiconductor material such as silicon carbide (SiC), gallium arsenic (GaAs), indium arsenide (InAs), or indium phosphide (InP). The substrate 102 may also include an alloy semiconductor such as silicon germanium, silicon germanium carbide, gallium arsenic phosphide, and gallium indium phosphide. In some embodiments, the substrate 102 may include a semiconductor-on-insulator (SOI) structure. For example, the substrate 102 may include a buried oxide layer formed by a process such as separation by implanted oxygen (SiMOX) or other suitable technique such as wafer bonding and grinding.

In some embodiments, the substrate 102 may also include various p-type doped regions and/or n-type doped regions. The doped regions may include n-well, p-well, lightly doped region (LDD), heavily doped source/drain (S/D), and various channel doping profiles configured to form various integrated circuits (IC) devices such as transistors, for example, metal-oxide-semiconductor field-effect transistor (MOS), imaging sensors, and light-emitting diode (LED). Passive devices such as resistors and capacitors may have been formed in the substrate 102. The various devices may further comprise silicide disposed on S/D. gate and other device features for reduced contact resistance and enhance process compatibility when coupled between devices through local interconnections.

The conductive feature 104 may include a source electrode, a drain electrode, or a gate electrode. Alternatively, the conductive features 104 may be a silicide feature disposed on a source, drain, or gate electrode from a sintering process introduced by at least one of the processes including thermal heating, laser irradiation or ion beam ion beam mixing. The silicide feature may be formed on polysilicon gate known as “polycide gate” or may be formed on source/drain known as silicide by a self-aligned silicide technique. As the MIM structure may also be formed in the higher metallization layers in the back end of line (BEOL) stage after the active devices such as transistors have been formed in the substrate, in some embodiments, the conductive feature may include a conductive wire or contact formed in a metallization layer formed over the substrate. The conductive features 104 may include wires or contacts made of materials such as gold (Au), cobalt (Co), copper (Cu), aluminum (Al), other suitable metal, or other suitable electrically conductive materials such as polysilicon.

As shown in FIG. 2, after individual devices such as transistors, capacitors, resistors, and other devices are formed in front end of line (FEOL) stage, multiple metallization layers may be formed in the BEOL stage to interconnect the individual devices. The metallization layers may include a first intermetal dielectric (IMD) layer 106, a second intermetal dielectric layer 108, and a third intermetal dielectric layer 110 formed on the substrate 102. The IMD layers 106, 108, and 110 may include a material of at least one of silicon oxide, a low dielectric constant (low-k) material, other suitable dielectric materials or a combination thereof. The low-k material may include fluorinated silica glass (FSG), phosphosilicate glass (PSG), borophosphosilicate glass (BPSG), carbon doped silicon oxide (SiOₓC_{y}), black polyimide, and other materials with low dielectric constant.

Various metallization structures (not shown) may be formed in each of the IMD layers 106, 108, and 110. For example, conductive plugs or metal wires may be formed to extend through one or some of the IMD layer 106, the IMD layer 108, and the IMD layer 110. The metallization structures may include electrically conductive materials such as any of gold (Au), cobalt (Co), silver (Ag), copper (Cu), and polysilicon. In some embodiments, etch stop layers 120 may be formed between adjacent IMD layers 106, 108, 110. In some embodiments, as shown in FIG. 2, the etch stop layers 120 may include a first etch stop layer 120A, a second etch stop layer 120B, and a third etch stop layer 120C. In some embodiments, the first etch stop layer 120A is a multilayer structure. For example, the first etch stop layer 120A includes a two or more dielectric layers, such as two or more SiC layers. In some embodiments, the second etch stop layer 120B includes a single dielectric layer, such as a single SiN layer. In some embodiments, the third etch stop layer 120C is a multilayer structure. For example, the third etch stop layer 120C includes two or more dielectric layers, such as two or more SiC layers.

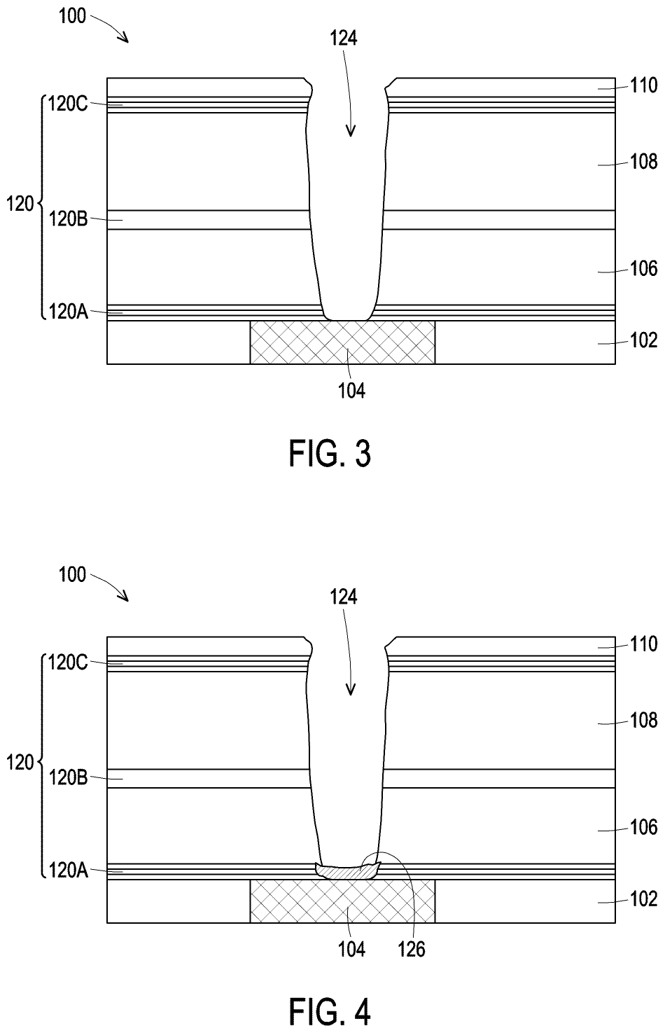

In FIG. 3, an opening 124 is formed to extend through the IMD layers 106, 108, 110 and the etch stop layers 120 and to expose the underneath conductive feature 104. The opening 124 may be formed by depositing and patterning a photoresist layer (not shown) and patterning the IMD layers 106, 108, 110 and the etch stop layers 120. The opening 124 may include a deep trench or an elongate hole with cross section in a circular, rectangular, or other suitable shape extending vertically through the IMD layers 106, 108, 110 and the etch stop layers 120. In some embodiments, the opening 124 may also be formed by processes such as dual damascene process. During the manufacturing processes of the MIM structure, the conductive feature 104 exposed to the atmosphere is easily oxidized. Oxidation of the conductive feature 104 not only increases resistance, but also causes reliability degradation due to weakened adhesion at the interfaces of the conductive features. Therefore, in some embodiments, a pre-clean process is performed to reduce the amount of the oxide layer on the conductive feature 104. When the conductive feature 104 includes a copper contact, the pre-clean process is performed by a hydrogen (H₂) plasma to remove CuOₓ on the copper contact.

As shown in FIG. 4, a metal layer 126 is formed on the conductive feature 104 exposed within the opening 124. The metal layer 126 may have a thickness ranging from about 20 Å to about 100 Å. To maintain sufficient space for forming an MIM structure in the opening 124, according to some embodiments, the metal layer 126 is formed by a deposition process that has much higher selectivity to the conductive feature 104 than to the dielectric materials, including the exposed surfaces of the IMD layers 106, 108, 110 and the etch stop layers 120 in the opening 124. In some embodiments, the deposition process of depositing the metal layer 126 on the conductive feature 104 has a selectivity of at least two times higher than depositing the metal layer 126 on the dielectric materials. In the selective deposition process, the energy required to decompose the source gas into the metal attached on the surface of the conductive feature 104 is much less than the energy required to decompose the source gas into metal attached on the surface of the IMD layers 106, 108, 110 and the etch stop layers 120. Therefore, the selective deposition process allows the metal layer 126 to be formed on the surface of the conductive feature 104 while the IMD layers 106, 108, 110 and the etch stop layers 120 remain exposed within the opening 124 and substantially free of the metal layer 126. According to some embodiments, the energy required to deposit the metal layer 126 on the conductive feature 104 is less than a half of the energy required to deposit the metal layer 126 on the sidewall of the opening 124.

In some embodiments, the selective deposition process includes a selective cobalt (Co) deposition process that decomposes a Co-containing gas precursor into Co deposited on the conductive feature 104. The Co-containing gas may include dicarbonylcyclopentadieny cobalt (C₅H₅)Co(CO)₂. The selective Co-deposition process may be performed using NH₃/H₂ as reactant gas at about 200°° C. to about 300° C. under a pressure of about 2 torr to about 10 torr. On the surface of the conductive feature 104, the energies required for breaking the first Co—CO and second Co—CO bonds of (C₅H₅)Co(CO)₂ are much lower than the energies required on the surface of the IMD layers 106. 108, 110 and the etch stop layers 120. As a result, Co is deposited on the conductive feature 104 while other surface areas of the opening 124 remain exposed and substantially Co free. According to some embodiments, when the conductive feature 104 is made of copper, the energy required to deposit Co onto the copper conductive feature 104 may be as low as about 40 kcal/mole compared to 99.2 kcal/mol required for depositing Co on a low-k dielectric material such as the IMD layers 106, 108, 110, and the etch stop layers 120 exposed within the opening 124. The selectively formed metal layer 126 may also include other materials such as one or more of Co, Ta, Ru, W, or other suitable materials.

The selectively formed metal layer 126 may prevent the diffusion of the material of the conductive feature 104 to a certain extent. At high temperature, penetration of the conductive material becomes much more active and cannot be effectively blocked by the metal layer 126. According to some embodiments, a plasma treatment may be applied to change the composition of the metal layer 126 by introducing barrier material from the plasma treatment therein. As a result, the effect of blocking the diffusion of the conductive material may be enhanced. For example, a plasma treatment 131 is performed after the selective deposition process, and the metal layer 126 is converted to a barrier layer 127. In some embodiments, the plasma treatment 131 is a nitrogen plasma treatment, and the barrier layer 127 includes a metal nitride. Other plasma may be used instead of nitrogen plasma for the plasma treatment 131, and the barrier layer 127 may be a composite material including the material of the metal layer 126 and the material from the plasma treatment 131. In some embodiments, the material from the plasma treatment 131 is a barrier material, such as nitrogen. The plasma treatment 131 does not substantially affect the dielectric materials, such as the IMD layers 106, 108, 110 and the etch stop layers 120.

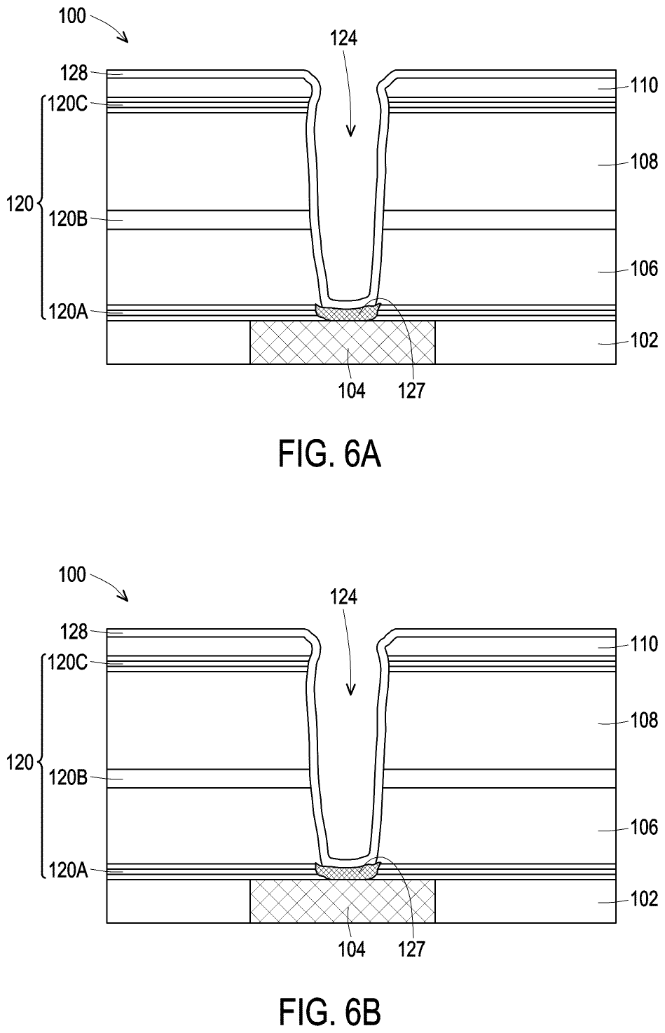

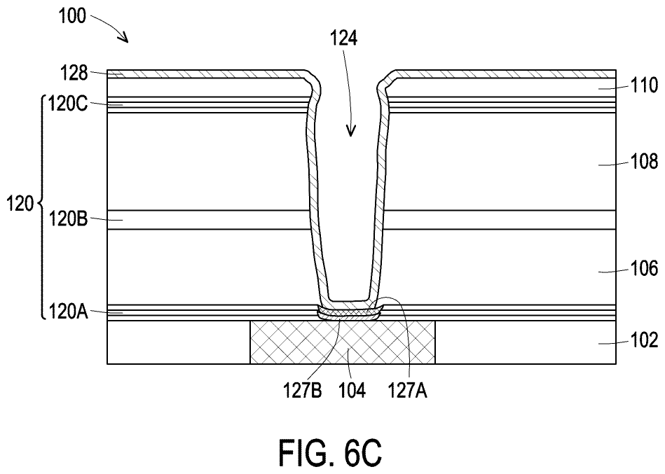

In the embodiment as shown in FIG. 6A, the barrier layer 127 may have a substantially even distribution of nitrogen across the thickness thereof. Alternatively, nitrogen contained in the barrier layer 127 may have a gradient concentration profile of which the nitrogen concentration decreases from a top surface of the barrier layer as shown in FIG. 6B. In some other embodiments, the barrier layer 127 may include a two-layer structure, including a top barrier layer 127A made of a top portion of the metal layer 126 that has been treated by the nitrogen plasma and a bottom barrier layer 127B made of the remaining metal layer 126 that has not been subject to the plasma treatment. The nitrogen contained in the top barrier layer 127A may have an even distribution of nitrogen across the thickness or a gradient concentration profile of which nitrogen concentration gradually decreasing from the top surface of the barrier layer 127A as shown in FIG. 6C.

In FIG. 6, a conductive layer 128 is formed on the barrier layer 127, the sidewall of the opening 124, and a top surface of the IMD layer 110. The conductive layer 128 is a first metal layer, that is, a first or bottom electrode, in the metal-insulator-metal (MIM) capacitor to be formed in the opening 124. The conductive layer 128 may include an electrically conductive material, such as one or more of titanium (Ti), aluminum copper alloy, titanium nitride (TiN), aluminum, copper, tungsten, tungsten nitride, platinum (Pt), palladium (Pd), metal silicide, or other suitable materials. The conductive layer 128 may be formed by a chemical vapor deposition (CVD) process, an atomic layer deposition (ALD) process, or other suitable process. In some embodiments, the conductive layer 128 is a conformal layer and is formed by a conformal process, such as an ALD process.

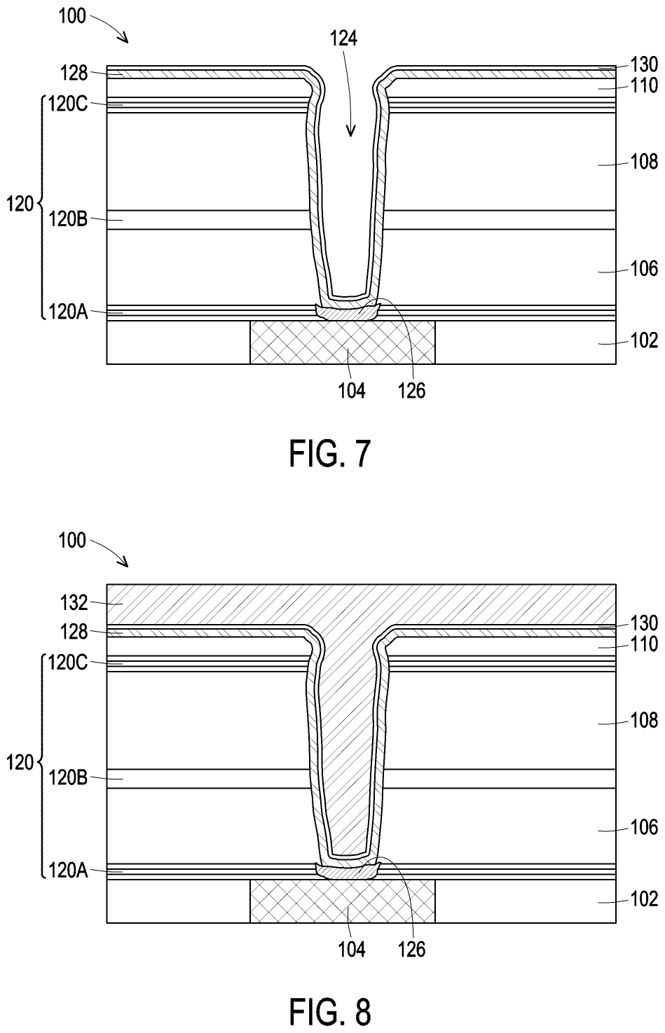

In FIG. 7. a dielectric layer 130 is formed on the conductive layer 128. The dielectric layer 130 is the “insulator” of the metal-insulator-metal capacitor to be formed in the opening 124. In some embodiments, the dielectric layer 130 may have a thickness ranging from about 1 nm to about 3 nm. The dielectric layer 130 may include a high-k dielectric material such as SiO₂, AlO, LaO, ZrO, TaO, Al₂O₃, HfO₂, other suitable dielectric material, and/or combinations thereof. The dielectric layer 130 may be formed by CVD, low pressure CVD (LPCVD), ALD, PVD, or other suitable processes. In some embodiments, the dielectric layer 130 is a conformal layer and is formed by a conformal process, such as an ALD process.

In FIG. 8, another conductive layer 132 is formed on the dielectric layer 130. The conductive layer 132 is a second metal layer, that is, a second or top electrode, in the metal-insulator-metal (MIM) capacitor formed in the opening 124. The conductive layer 132 may include an electrically conductive material, such as one or more of aluminum copper alloy, titanium nitride (TiN), aluminum, copper, tungsten, tungsten nitride, metal silicide, or other suitable materials. In some embodiments, the conductive layer 132 and the conductive layer 128 include the same material. The conductive layer 132 may be formed by a chemical vapor deposition (CVD) process, an atomic layer deposition (ALD) process, or other suitable process. In some embodiments, the conductive layer 132 is a conformal layer and is formed by a conformal process, such as an ALD process.

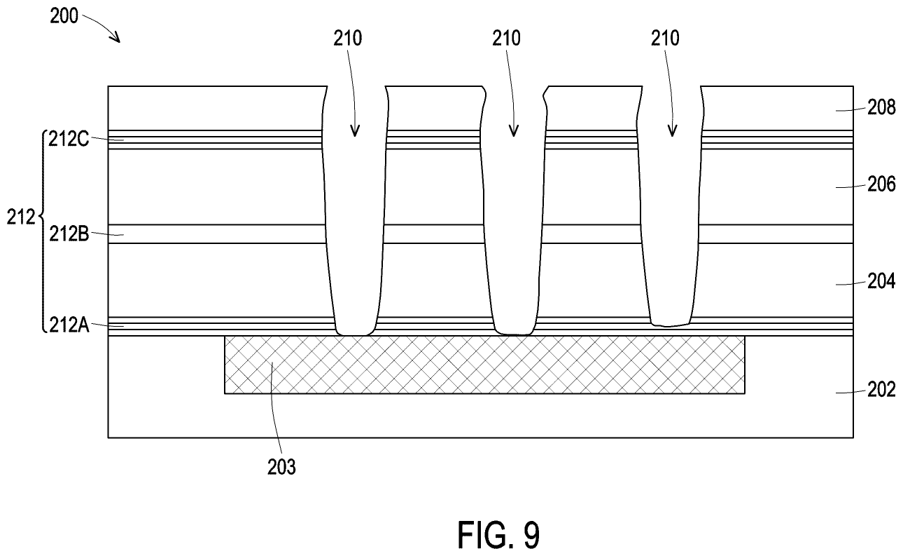

FIGS. 9-12 show a semiconductor device structure that includes a MIM capacitor in various manufacturing stages according to alternative embodiments. As shown in FIG. 9, the semiconductor device structure 200 includes multiple metallization layers, such as IMD layers 202, 204, 206, and 208. Before the metallization layers are formed in the BEOL stage, various devices, including the active and passive devices, may have been formed in a substrate on which the IMD layers 202, 204, 206, and 208 are formed. The IMD layers 202, 204, 206, and 208 may include a material of at least one of silicon oxide, a low dielectric constant (low-k) material, other suitable dielectric materials or a combination thereof. The low-k material may include fluorinated silica glass (FSG), phosphosilicate glass (PSG), borophosphosilicate glass (BPSG), carbon doped silicon oxide (SiOₓC_{y}), black polyimide, and other materials with low dielectric constant.

Various interconnection or metallization structures such as metal wires, conductive plugs, vias, or other conductive structures, may be formed in each of the IMD layers 202, 204, 206, 208. For example, the IMD layer 202 may include a conductive feature 203 formed therein. The conductive feature 203 may include a metal wire or a contact made of electrically conductive materials such as gold (Au), cobalt (Co), copper (Cu), aluminum (Al), other suitable metal, or other suitable electrically conductive materials such as polysilicon. Other metallization structures such as contact plugs or vias may also be disposed in the IMD layer 202. In some embodiments, etch stop layers 212 may be formed between adjacent IMD layers 202, 204, 206, 208. In some embodiments, the etch stop layers 212 includes a first etch stop layer 212A, a second etch stop layer 212B, and a third etch stop layer 212C. The etch stop layers 212A, 212B, 212C may include the same materials as the etch stop layers 120A, 120B, 120C, respectively.

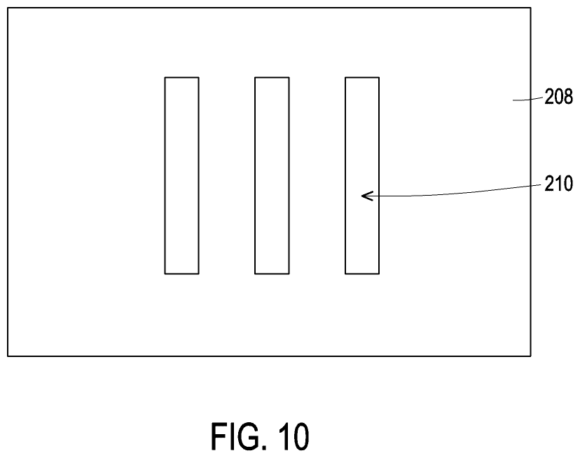

In the embodiment as shown in FIGS. 9-12, three openings 210 are formed to extend through the IMD layers 204, 206, and 208 to expose the underneath conductive feature 203. The openings 210 may include a deep trench or an elongated hole with a circular or other shape of cross sections extending vertically through the IMD layers 204, 206, and 208. It will be appreciated that the number of openings may vary depending on specific need. In addition, the openings 210 may also extend through more or less than three IMD layers as desired. FIG. 10 shows a top view of the openings 210 in the forms of deep trenches arranged side by side with each other. The openings 210 may also be arranged in different forms as desired. The openings 210 may be formed simultaneously or by different processes. In some embodiments, the openings 210 may also be formed with different depths for forming a MIM capacitor with different capacitance according to some embodiments. The openings 210 may be as deep as about 1.65 μm with a top critical dimension as narrow as from about 0.1 μum to about 0.13 μm. That is, the openings 210 may have aspect ratios from about 13 to about 16 to form the MIM capacitor with capacitances of about 350 fF to about 1000 fF.

During the manufacturing processes of the MIM structures, the conductive feature 203 exposed to the atmosphere is easily oxidized. Oxidation of the conductive feature 203 not only increases resistance, but also causes reliability degradation due to weakened adhesion at the interfaces of the conductive features. Therefore, in some embodiments, a pre-clean process is performed to reduce the amount of the oxide layer on the conductive feature 203. When the conductive feature 203 includes a copper contact, the pre-clean process is performed a hydrogen (H₂) plasma to remove CuOx on the conductive feature 203.

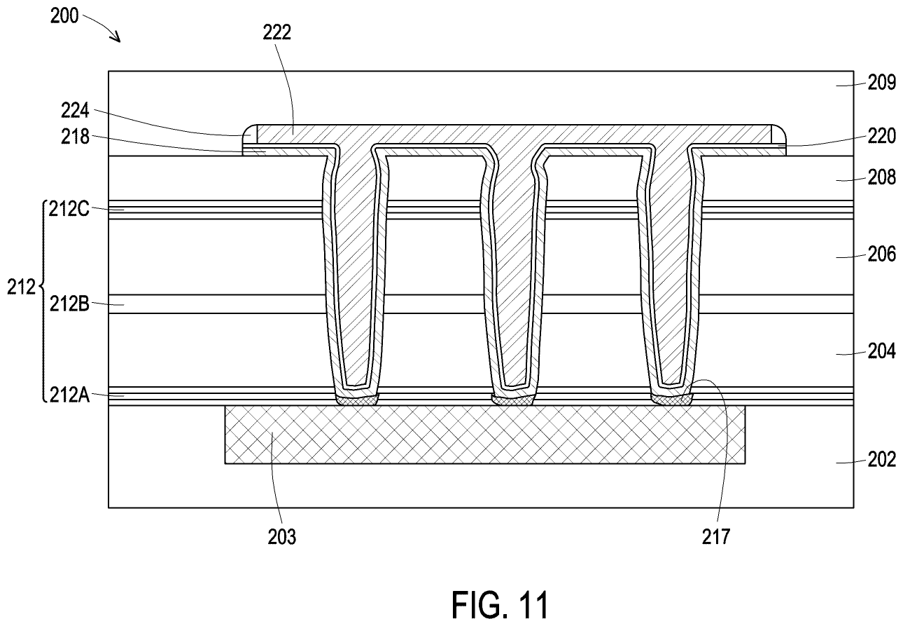

As shown in FIG. 11, a metal layer 216 is formed on the conductive feature 203 exposed within each of the openings 210. To maintain sufficient space for forming an MIM structure in the deep openings 210, according to some embodiments, the metal layers 216 may be formed by a deposition process that has much higher selectivity to the conductive feature 203 than to the dielectric materials, including the exposed surfaces of the IMD layers 204, 206, 208 and the etch stop layers 212 in the openings 210. The selective deposition process allows the metal layers 216 to be formed on the surface of the conductive features 203 while the IMD layers 204, 206, 208 and the etch stop layers 212 remain exposed within the openings 210.

In some embodiments, the selective deposition process includes a selective cobalt (Co) deposition process that decomposes a Co-containing gas precursor into Co deposited on the conductive features 203. The Co-containing gas may include dicarbonylcyclopentadieny cobalt (C₅H₅)Co(CO)₂. The selective Co-deposition process may be performed using NH₃/H₂ as reactant gas at about 200° C. to about 300° C. under a pressure of about 2 torr to about 10 torr. On the surface of the conductive features 203, the energies required for breaking the first Co—CO and second Co—CO bonds of (C₅H₅)Co(CO)₂ are much lower than the energies required on the surface of the IMD layers 204. 206, and 208. As a result, Co is deposited on the conductive features 203 while other surface areas of the openings 210 remain exposed. The selectively formed metal layer 216 may also include other materials such as CoTa, RuCo, RuN, RuTa, CoW, WN, or other suitable materials.

According to some embodiments, the metal layer 216 is converted to a barrier layer 217. In some embodiments, a plasma treatment is performed to convert the metal layer 216 to the barrier layer 217. The plasma treatment may be the plasma treatment 131, and the barrier layer 217 may include the same material as the barrier layer 117. The barrier layers 217 provide improved barrier effect to further prevent the diffusion of the material of the conductive feature 203.

As shown in FIG. 11, a conductive layer 218 is formed on each of the barrier layer 217, the sidewalls of the openings 210, and a top surface of the IMD 208. The conductive layer 218 are the first metal layers, that is, first or bottom electrode, of the metal-insulator-metal (MIM) capacitor to be formed in each of the openings 210. The conductive layer 218 may include an electrically conductive material, such as one or more of aluminum copper alloy, titanium nitride (TiN), aluminum, copper, tungsten, tungsten nitride, metal silicide, or other suitable metals. The conductive layer 218 may be formed by a chemical vapor deposition (CVD) process, an atomic layer deposition (ALD) process, or other suitable processes. In some embodiments, the conductive layer 218 is a conformal layer and is formed by a conformal process, such as an ALD process.

A dielectric layer 220 is formed on the conductive layer 218. The dielectric layer 220 is the insulator of the metal-insulator-metal capacitor to be formed in each of the openings 210. In some embodiments, the dielectric layer 220 may have a thickness ranging from about 1 nm to about 3 nm. The diclectric layer 220 may be formed by high-k dielectric materials such as SiO₂, AlO, LaO, ZrO, TaO, Al₂O₃, HfO₂, other suitable dielectric material, and/or combinations thereof. The dielectric layer 220 may be formed by CVD, low pressure CVD (LPCVD). ALD, PVD, or other suitable processes. In some embodiments, the dielectric layer 220 is a conformal layer and is formed by a conformal process, such as an ALD process.

A conductive layer 222 is formed on the dielectric layer 220. The conductive layer 222 is a second metal layer, that is, a second or top electrode, in the metal-insulator-metal (MIM) capacitor formed in each of the openings 210. The conductive layer 222 may include an electrically conductive material, such as one or more of aluminum copper alloy, titanium nitride (TiN), aluminum, copper, tungsten, tungsten nitride, metal silicide, or other suitable metals. In some embodiments, the conductive layer 222 and the conductive layer 218 include the same material. The conductive layer 222 may be formed by a chemical vapor deposition (CVD) process, an atomic layer deposition (ALD) process, or other suitable process. In some embodiments, the conductive layer 222 is a conformal layer and is formed by a conformal process, such as an ALD process.

An insulation layer 209 is formed on the conductive layer 222 and the dielectric layer 208. The insulation layer 209 may include any suitable dielectric material such as the material of the dielectric layers 204, 206, 208, or 220. In some embodiments, spacers 224 are formed on the sidewalls of the conductive layer 222 over the dielectric layer 220 as shown in FIG. 11.

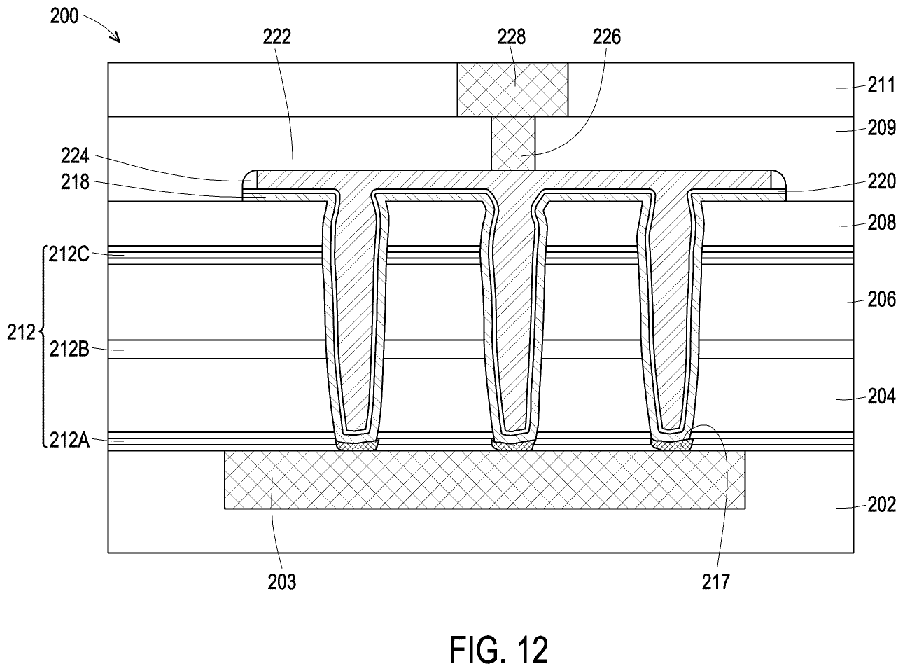

In FIG. 12, a conductive feature 226 is formed in the insulation layer 209, and a metallization layer is formed on the insulation layer 209. The metallization layer may include a dielectric layer 211 and a conductive feature 228 formed in the dielectric layer 211. The conductive feature 228 is electrically connected to the conductive feature 226. The conductive feature 226 may be a via structure or a conductive plug that is electrically connected to the MIM capacitor located therebelow, and the conductive feature 228 may be a conductive wire. The conductive features 226 and 228 may include the same material as the conductive feature 203.

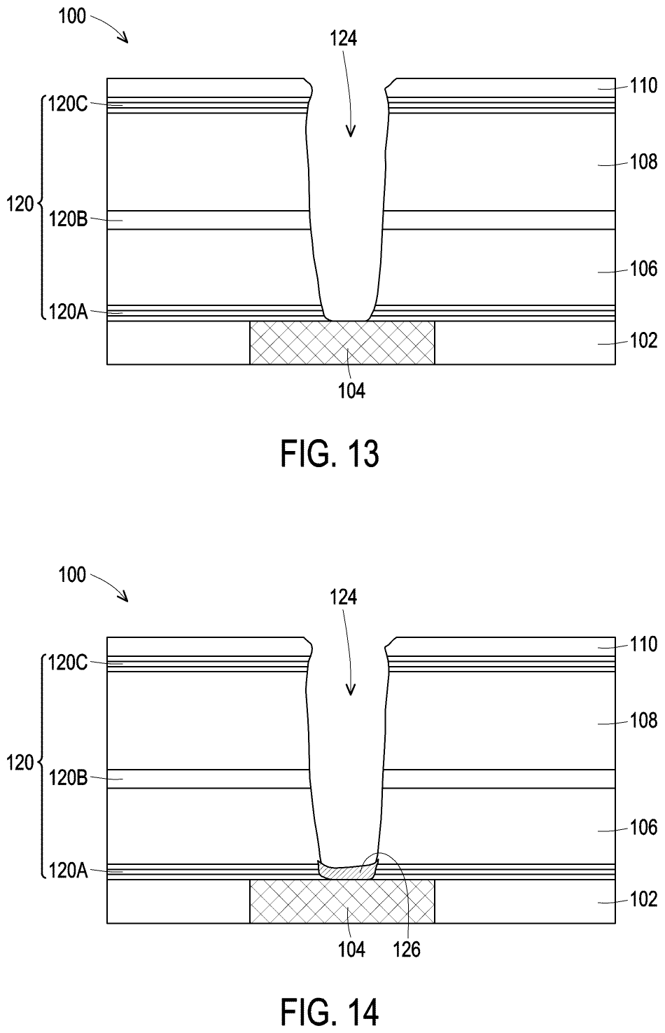

FIGS. 13-18 shows various stages of manufacturing a 3D MIM structure in a semiconductor device structure according to some embodiments. Similar to the semiconductor device 100 as shown in FIGS. 1-8, the semiconductive device structure 300 as shown in FIGS. 13-17 includes the substrate 102, the plurality of IMD layers 106, 108, and 110 formed on a substrate 102, and the etch stop layers 120 formed between adjacent IMD layers 106, 108, 110. The conductive feature 104 is formed in the substrate 102. Alternatively, the substrate 102 may include a metallization layer in which the conductive feature 104 is formed therein. The opening 124 is formed to extend through the IMD layers 106, 108, 110 and the etch stop layers 120 and to expose the underneath conductive feature 104. The opening 124 may include a deep trench or an elongate hole with cross section in a circular, rectangular, or other shape extending vertically through the IMD layers 106, 108, 110 and the etch stop layers 120. During the manufacturing processes of the MIM structure, the conductive feature 104 exposed to the atmosphere is easily oxidized. Oxidation of the conductive feature 104 not only increases resistance, but also causes reliability degradation due to weakened adhesion at the interfaces of the conductive features. Therefore, in some embodiments, a pre-clean process is performed to reduce the amount of the oxide layer on the conductive feature 104. When the conductive feature 104 includes a copper contact, the pre-clean process is performed a hydrogen (H₂) plasma to remove CuOx on the conductive feature 104.

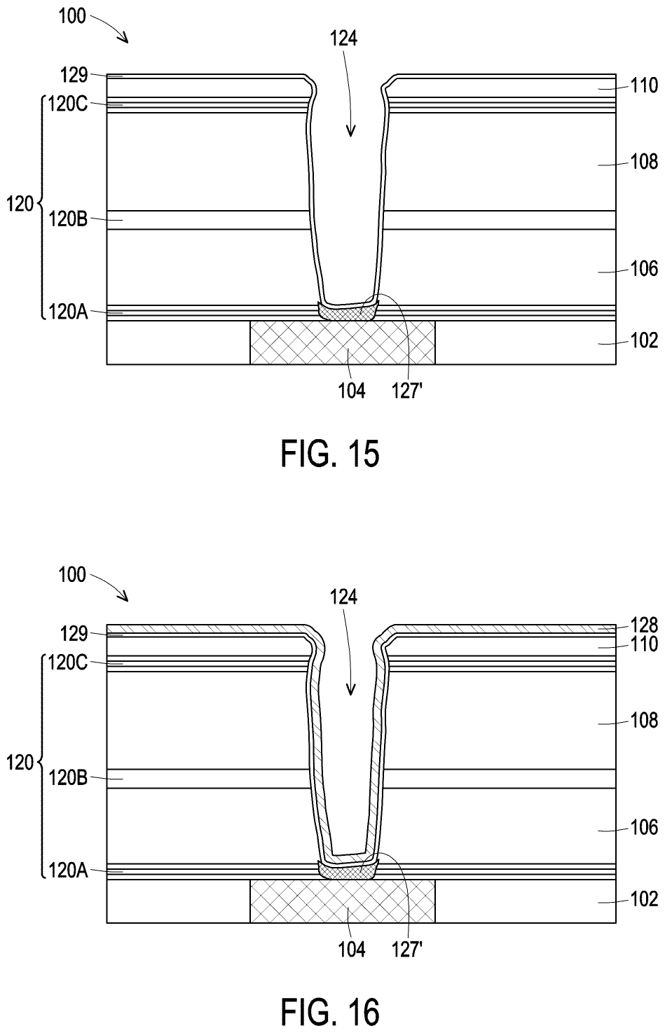

As shown in FIG. 14, the metal layer 126 is formed on the conductive feature 104 exposed within the opening 124. As discussed above, the selectively formed metal layer 126 may be insufficient to prevent the diffusion of the conductive material of the conductive feature 104 at high temperatures. According to some embodiments, as shown in FIG. 15, a barrier layer 129 made of Ta, TaN, or other materials is formed on the metal layer 126, the sidewall of the opening 124, and a top surface of the IMD layer 110. The combination of the selectively formed metal layer 126 and the barrier layer 129 may effectively block the diffusion of the conductive material of the conductive feature even when the temperature rises up to 400° C. or above during the subsequent processes for forming the MIM capacitors. Although the sidewall of the opening 124 is covered by the barrier layer 129, the single-structure of the barrier layer 129 does not significantly reduce the top critical dimension of the opening 124. Therefore, a sufficient space within the opening 124 can be maintained for forming a MIM capacitor. In some embodiments, the barrier layer 129 is formed by a PVD process. During the PVD process, the material from a source target, such as Ta or TaN, may diffuse into the metal layer 126. As a result, the metal layer 126 may be converted into a barrier layer 127′ that has at least a portion of the originally deposited metal layer converted into a composite or alloy structure. In some embodiments, the barrier structure 127′ includes a first portion of the as-deposited metal layer 126 and a second portion of an alloy or composite of the as-deposited metal layer 126 diffused with material produced from the PVD process. The second portion may have a gradient concentration profile of the diffused material decreasing from the top surface of the barrier structure 127′ to the bottom surface of the barrier layer 127′ as a result of the PVD process. In some embodiments, the second portion includes a CoTa alloy.

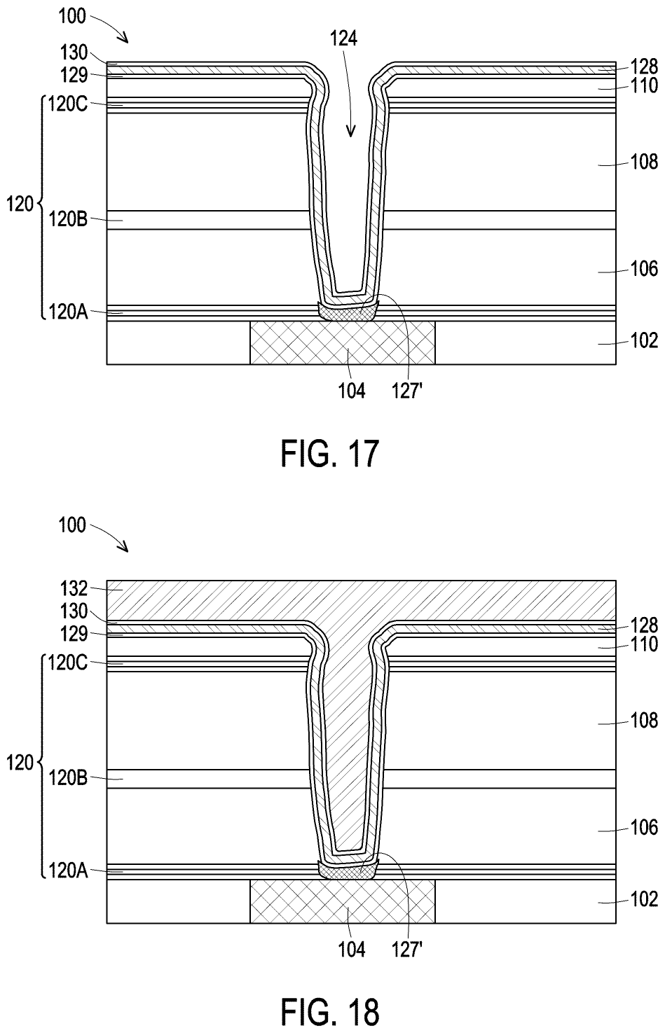

In FIG. 16, the conductive layer 128 is formed on the barrier layer 129. In FIG. 17, the dielectric layer 130 is formed on the conductive layer 128. In FIG. 18, the conductive layer 132 is formed on the dielectric layer 130 and fills the opening 124. The combination of the barrier structure 127′ and the barrier layer 129 may also applied to the embodiments as shown in FIG. 12. That is, the barrier layer 217 may be replaced with the dual-layer structure including the barrier structure 127′ and the barrier layer 129. More specifically, a metal layer 126 is selectively formed on the conductive feature 203 at the bottom of each opening 210 (FIG. 9), the barrier layer 129 is then conformally formed in the openings 210 while at least a portion of the metal layer 126 is converted into a composite or alloy structure.

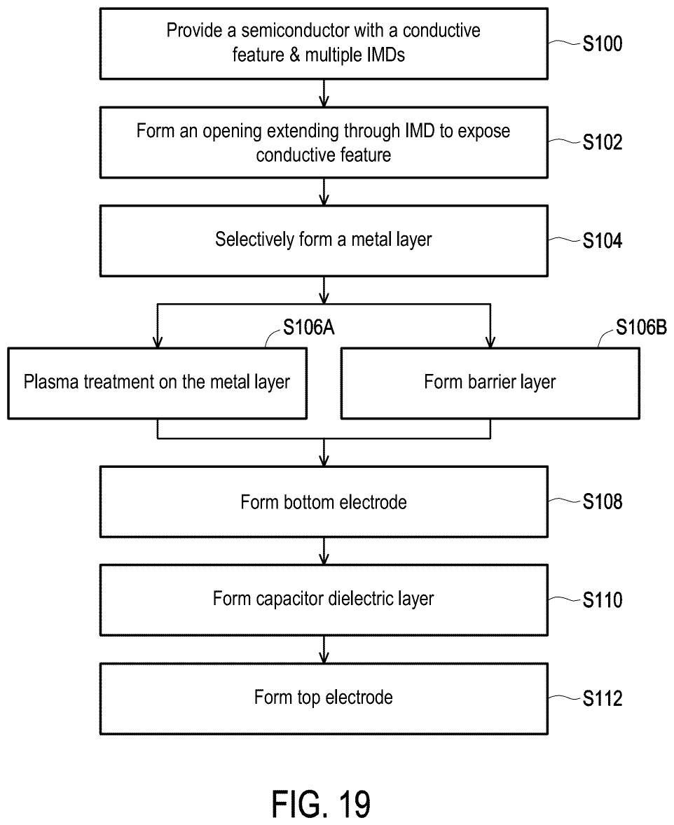

FIG. 19 shows a method of forming an MIM capacitor in a semiconductor device structure according to some embodiments. The various steps of the method may be referred to the processes as shown in FIGS. 1-18. At block S100, a semiconductor substrate with a conductive feature and multiple IMD layers, for example, the conductive feature 104 and IMD layers 106-110 as shown in FIGS. 2 and 13, is provided. The conductive feature may include a copper contact or other metal wire or conductive structure, for example. At block S102, an opening, for example, the opening 124 as shown in FIGS. 4 and 15, is formed to extend through the multiple IMD layers and to expose the conductive feature. At block S104, a metal layer (for example, the metal layer 126 in FIGS. 4 and 14) is selectively formed on the conductive feature exposed within the opening. In some embodiment, the metal layer is in direct contact with the conductive feature. The metal layer may be formed by a selective deposition process such as selective Co-deposition process that selectively deposits the metal or conductive materials on the exposed conductive feature. As shown in FIGS. 4 and 14, after the metal layer is formed in the selective deposition process, the sidewall of the opening remains exposed. The metal layer may include a Ta layer to function as a barrier layer to prevent the conductive materials of the conductive feature from diffusing into the MIM capacitor to be formed within the opening.

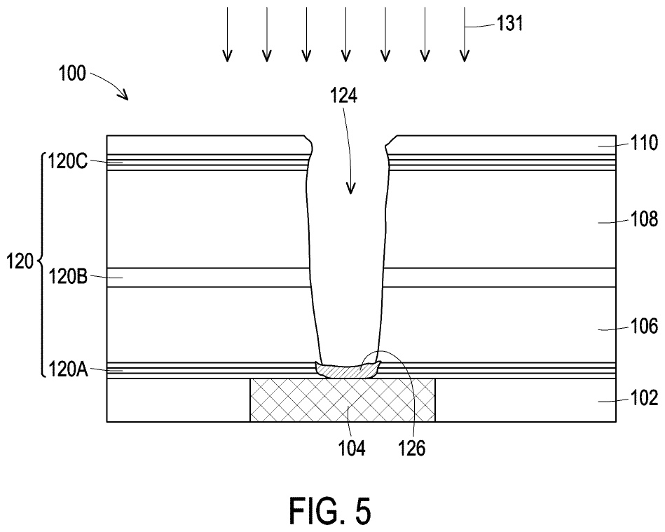

As some steps of forming the MIM capacitor are performed high temperature, the metal layer itself may provide insufficient effect for blocking the diffusion of the conductive materials of the conductive feature. Therefore, at block S106A, a plasma treatment may be performed to convert the metal layer to a barrier layer. For example, as shown in FIG. 5, materials such as nitrogen may be diffused into the metal layer 126 by the plasma treatment to convert the metal layer 126 to a barrier layer 127, which may be a metal nitride, as shown in FIGS. 6A-6B. Alternatively, at block S106B, a barrier layer, for example, the barrier layer 129 as shown in FIG. 15, may be formed along the exposed surface of the semiconductor device structure. As the barrier layer covering the sidewall of the opening is a single layer, the thickness may be controlled thin enough to avoid significant overhang formed at the top of the opening. On the other hand, a bi-layer structure, including the metal layer 126 and the barrier layer 129, formed between the conductive feature and the MIM capacitor to be formed within the opening provides promising blocking effect to prevent diffusion of the conductive feature. In some embodiments, the metal layer 126 may be converted to an alloy or a composite layer after the formation of the barrier layer 129. The processes in the S106A or S106B are selected based on specific process or device parameters as desired.

At block S108, a first conductive layer serving as the bottom electrode is formed along a surface profile of the semiconductor device structure. For example, as shown in FIG. 6, the conductive layer 128 is formed on the barrier layer 127, a sidewall of the opening 124, and a top surface of the IMD 110; or as shown in FIG. 16, the conductive layer 128 is formed along the surface of the barrier layer 129. A dielectric layer, for example, the dielectric layer 130 as shown in FIGS. 7 and 17, to serve the insulator (capacitor dielectric) is then formed on the first conductive layer at block S110. At block S112, a second conducive layer, such as the conductive layer 132 as shown in FIGS. 8 and 18, is formed on the dielectric layer 130.

The method presented in FIG. 19 shows the processes for forming an MIM capacitor extending through multiple IMD layers in a single opening. It will be appreciated that multiple openings may be formed at block S102. The MIM capacitor may be formed in the multiple openings as shown in FIG. 11.

Embodiments of the present disclosure provide a semiconductor device structure and methods of forming the same. In some embodiments, the semiconductor device structure includes a barrier layer or a metal layer with a barrier layer formed between an MIM capacitor and a conductive feature. Some embodiments may achieve advantages. For example, the barrier layer or the metal layer and the barrier layer prevent the diffusion of the material from the conductive feature into the MIM capacitor.

An embodiment is a method. The method includes forming an opening extending through one or more first dielectric layers to expose a conductive feature thereunder and forming a barrier structure on the conductive feature. The forming the barrier structure includes selectively forming a metal layer on the conductive feature and performing a plasma treatment on the metal layer to convert at least a portion of the metal layer into a barrier structure. The method further includes depositing a first conductive layer on the barrier structure in the opening, depositing a second dielectric layer on the first conductive layer, and depositing a second conducive layer on the dielectric layer.

Another embodiment is a method. The method includes forming an opening extending through one or more first dielectric layers to expose a conductive feature, selectively forming a metal layer on the conductive feature, depositing a conformal barrier layer in the opening, converting at least a portion of the metal layer into an alloy or composite structure while depositing the conformal barrier layer, depositing a first conductive layer on the conformal barrier layer in the opening, depositing a second dielectric layer on the first conductive layer, and depositing a second conducive layer on the second dielectric layer.

A further embodiment is a structure. The structure includes a conductive feature disposed over a substrate and a barrier structure disposed on the conductive feature. The barrier structure includes a metal layer with at least a portion containing a barrier material, and the barrier material has a concentration profile that decreases along a direction from a top surface to a bottom surface of the barrier structure. The structure further includes a metal-insulator-metal (MIM) structure disposed on the barrier structure, and the MIM structure includes a first conductive layer disposed over the barrier structure, a dielectric layer disposed on the first conductive layer, and a second conductive layer disposed on the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming an opening extending through one or more first dielectric layers to expose a conductive feature thereunder;
forming a barrier structure on the conductive feature, comprising:
selectively forming a metal layer on the conductive feature; and
performing a plasma treatment on the metal layer to convert at least a portion of the metal layer into a barrier structure;
depositing a first conductive layer on the barrier structure in the opening;
depositing a second dielectric layer on the first conductive layer; and
depositing a second conducive layer on the dielectric layer.

2. The method of claim 1, further comprising forming the opening with an aspect ratio higher than about 13.

3. The method of claim 1, further comprising performing the plasma treatment using a nitrogen-containing plasma.

4. The method of claim 3, wherein the barrier structure has a nitrogen concentration decreasing from a top surface to a bottom surface thereof.

5. The method of claim 1, wherein the metal layer comprises Co, Ta, Ru, or W.

6. The method of claim 1, further comprising converting the metal layer into a two-layer structure by the plasma treatment, wherein the two-layer structure includes the barrier structure and a remaining portion of the metal layer.

7. The method of claim 1, wherein the barrier structure includes a barrier material with a concentration gradually decreasing in a direction towards the conductive feature.

8. The method of claim 1, further comprising forming the metal layer on the conductive feature with a selectivity of at least two times higher than forming on the one or more first dielectric layers.

9. A method, comprising:
forming an opening extending through one or more first dielectric layers to expose a conductive feature;
selectively forming a metal layer on the conductive feature;
depositing a conformal barrier layer in the opening;
converting at least a portion of the metal layer into an alloy or composite structure while depositing the conformal barrier layer;
depositing a first conductive layer on the conformal barrier layer in the opening;
depositing a second dielectric layer on the first conductive layer; and
depositing a second conducive layer on the second dielectric layer.

10. The method of claim 9, further comprising forming the opening with an aspect ratio larger than about 13.

11. The method of claim 9, wherein the metal layer comprises Co, Ta, Ru, or W.

12. The method of claim 9, wherein the conformal barrier layer comprises Ta or TaN.

13. The method of claim 9, wherein a barrier material is introduced into the metal layer during deposition of the conformal barrier layer.

14. The method of claim 9, further comprising forming the metal layer on the conductive feature with a selectivity of at least two times higher than forming on the one or more first dielectric layers.

15. A semiconductor device structure, comprising:
a conductive feature disposed over a substrate;
a barrier structure disposed on the conductive feature, wherein the barrier structure comprises a metal layer with at least a portion containing a barrier material, and the barrier material has a concentration profile that decreases along a direction from a top surface to a bottom surface of the barrier structure; and
a metal-insulator-metal (MIM) structure disposed on the barrier structure, wherein the MIM structure comprises:
a first conductive layer disposed over the barrier structure;
a dielectric layer disposed on the first conductive layer; and
a second conductive layer disposed on the dielectric layer.

16. The semiconductor device structure of claim 15, wherein metal layer comprises Co, Ta, Ru, or W.

17. The semiconductor device structure of claim 15, wherein the barrier structure includes a plasma treated metal layer.

18. The semiconductor device structure of claim 15, wherein the barrier material includes nitrogen.

19. The semiconductor device structure of claim 15, further comprising a barrier layer conformally formed between the barrier structure and the MIM structure, and the barrier layer includes a material the same as the barrier material in the barrier structure.

20. The semiconductor device structure of claim 19, wherein the barrier layer includes Ta or TaN.
